(19) United States
(12) Patent Application Publication
(10) Pub. No.: US 2012/0114143 A1
(43) Pub. Date: May 10, 2012

(54) SOUND OUTPUT APPARATUS

(76) Inventor: Seiji WARAGAYA, Iwaki-city (JP)

(21) Appl. No.: 13/186,184

(22) Filed: Jul. 19, 2011

(30) Foreign Application Priority Data
Nov. 4, 2010 (JP) JP 2010-247645

(51) Int. Cl. H03G 5/00; H04B 1/00

(52) U.S. Cl. 381/98; 381/119

(57) ABSTRACT

A sound output apparatus includes a mixing unit configured to mix an L (left) channel voice signal and an R (right) channel voice signal to generate an L+WF signal and an R−WF signal containing a mix of a WF(woofer) channel voice signal, and power amplifiers which amplify the L+WF signal and R−WF signal. The outputs of the power amplifiers are BTL-connected to a WF channel speaker. Thus, the mixing unit provided in a previous stage of the power amplifiers generates the WF channel voice signal, which eliminates the necessity for a passive low pass filter in a subsequent power amplifier stage.

### PRIORITY CLAIM

This application claims the benefit of Japanese Patent Application No. 2010-247645, filed on Nov. 4, 2010, and which is incorporated by reference herein in its entirety.

### BACKGROUND

1. Field of the Invention

The present invention relates to sound output apparatuses, and it is particularly suitable for use in a sound output apparatus having a function which may provide a monaural output through bridge connection between two outputs of a stereo amplifier.

2. Description of the Related Art

Hitherto, a sound output apparatus applying BTL (Bridged Transless) connection has been provided. (Reference may be made to Japanese Unexamined Utility Model Registration Application Publication No. 59-195897, Japanese Unexamined Patent Application Publication No. 5-199594, and Japanese Unexamined Patent Application Publication No. 2002-345099, for example). BTL connection refers to a system in which two outputs (L channel and R channel outputs) of a stereo amplifier are bridge-connected to acquire a monaural output (output of L+R channels).

The use of BTL connection can double the voltage of the monaural output, compared with two stereo outputs without BTL connection. The use of BTL connection may further provide outputs of three channels of an L channel, an R channel, and an L+R channel only with a two-channel stereo amplifier.

FIG. 7 illustrates a configuration example of a sound output apparatus in the past applying BTL connection. As illustrated in FIG. 7, a BTL connection sound output apparatus includes a low pass filter (LPF) 106 and an L+R channel speaker (woofer speaker only for low-pitch sound) 107 in addition to an L channel power amplifier 101, an inverter buffer 102, an R channel power amplifier 103, an L channel speaker 104, an R channel speaker 105.

The L channel power amplifier 101 receives and amplifies the input of an L channel voice signal (called an L signal) and outputs the amplified voice signal (L signal, −L signal) through the positive phase output terminal and reverse phase output terminal, respectively. The symbol “−” indicates that the phase has been reversed. The L signal output from the L channel power amplifier 101 is input to the + terminal of the L channel speaker 104 and the LPF 106. The −L signal output from the L channel power amplifier 101 is input to the − terminal of the L channel speaker 104. Thus, the L signal of double voltage (2L signal) is output from the L channel speaker 104.

The inverter buffer 102 reverses the phase of the R channel voice signal (hereinafter, called an R signal) and outputs it to the R channel power amplifier 103. The R channel power amplifier 103 amplifies the −R signal output from the inverter buffer 102 and outputs the amplified voice signals (−R signal, R signal) through the positive phase output terminal and reverse phase output terminal, respectively. The −R signal is input to the − terminal of the R channel speaker 105 and the LPF 106. The R signal is input to the + terminal of the R channel speaker 104. Thus, the R signal (2R signal) of double voltage is output from the R channel speaker 105.

The LPF 106 only allows a low frequency component of the L signal output from the L channel power amplifier 101 and −R signal output from the R channel power amplifier 103 to pass through. The L signal of the low frequency component passed through the LPF 106 is input to the + terminal of the woofer speaker 107. The −R signal of the low frequency component passed through the LPF 106 is input to the − terminal of the woofer speaker 107. Thus, the L+R signal is output from the woofer speaker 107.

The sound output apparatus in the past may be required to include the passive LPF 106 in order to generate voice signals of the L+R component localized at the center position (or voice signals having the same phase at which the L component of the low frequency region and the R component of the low frequency region have a substantially equal intensity, such as vocal sound and base sound). Because the LPF 106 is required to process the voice signals amplified by the two power amplifiers 101 and 103, the circuit area as an analog circuit employing a passive element increases. It further disadvantageously increases the manufacturing cost of the sound output apparatus.

### SUMMARY

The present invention was made in order to solve the problems as described above. It is an object of the present invention to provide a BTL connection sound output apparatus in which a passive LPF is not necessary for generating a voice signal for a woofer, which may reduce the manufacturing cost.

In order to solve the problems, a sound output apparatus of the present invention includes a mixing unit which mixes an L (left) channel voice signal and an R (right) channel voice signal to generate a mixed signal of the L channel and a WF (woofer) channel and a mixed signal of the R channel and the WF channel, an L channel power amplifier which amplifies a mixed signal of the L channel and the WF channel, an R channel power amplifier which amplifies a mixed signal of the R channel and the WF channel. The output of the L channel power amplifier and the output of the R channel power amplifier are bridge-connected to a WF channel speaker.

According to the present invention configured as described above, a mixing unit provided in a previous stage of a power amplifier generates a voice signal for a WF channel. This may eliminate a passive low pass filter which has been required in a subsequent stage (or a previous stage of a WF channel speaker) of the power amplifier. In this case, the mixing unit is provided instead of a passive low pass filter. The mixing unit processes an analog voice signal amplified by the power amplifier, which allows implementation of the mixing unit at a lower cost than a passive low pass filter in the past implemented by a passive element. Thus, the present invention may eliminate the necessity for a passive low pass filter for generating a voice signal for a woofer in a sound output apparatus using bridge connection, which may reduce the manufacturing cost.

### BRIEF DESCRIPTION OF THE DRAWINGS

FIG. 1 illustrates an example of a sound output apparatus according to an embodiment;

FIG. 2 illustrates an example of the sound output apparatus according to this embodiment;

FIG. 3 illustrates an example of the sound output apparatus according to this embodiment;

FIG. 4 illustrates an example of the sound output apparatus according to a variation example of FIG. 1;

FIG. 5 illustrates an example of the sound output apparatus according to a variation example of FIG. 2;

FIG. 6 illustrates an example of the sound output apparatus according to a variation example of FIG. 3; and

FIG. 7 illustrates an example of a sound output apparatus in the past.

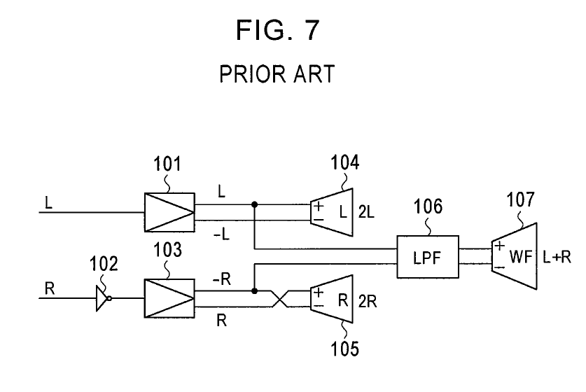

### DETAILED DESCRIPTION

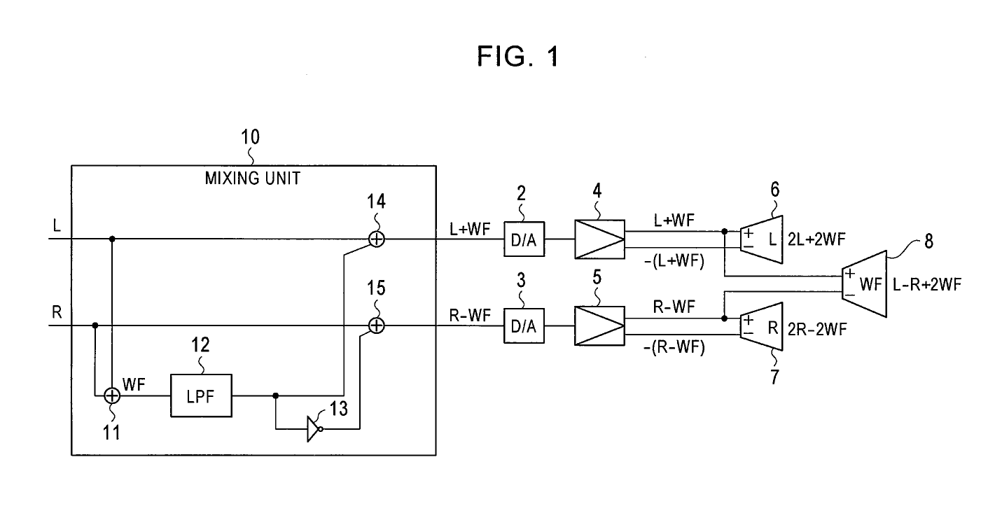

An embodiment of the present invention will be described below with reference to drawings. FIG. 1 illustrates a configuration example of a sound output apparatus according to an embodiment. As illustrated in FIG. 1, a sound output apparatus according to this embodiment includes a mixing unit 10, an L channel D/A converting unit 2, an R channel D/A converting unit 3, an L channel power amplifier 4, an R channel power amplifier 5, an L channel speaker 6, an R channel speaker 7 and a WF channel speaker 8.

The mixing unit 10 may be implemented by a DSP (Digital Signal Processor), for example, and functionally includes a first adding unit 11, a WF channel LPF 12, a phase inverting unit 13, a second adding unit 14 and a third adding unit 15. The mixing unit 10 mixes input of an L (left) channel voice signal (hereinafter, called an L signal) and R (right) channel voice signal (hereinafter, called an R signal) and generates and outputs a mixed signal of the L channel and the WF (woofer) channel and the mixed signal of the R channel and the WF channel.

More specifically, the first adding unit 11 included in the mixing unit 10 adds an L signal and R signal input to the mixing unit 10 and thus generates a WF channel (L+R channel) voice signal (hereinafter, called a WF signal). The WF channel LPF 12 allows a low frequency component of the WF signal generated by the first adding unit 11 to pass through. The phase inverting unit 13 inverts the phase of the WF signal passed through the WF channel LPF 12.

The second adding unit 14 adds the L signal input to the mixing unit 10 and the WF signal passed through the WF channel LPF 12 to generate an L+WF signal which is a mixed signal of the L channel and the WF channel. The third adding unit 15 adds the R signal input to the mixing unit 10 and the WF signal having the phase inverted by the phase inverting unit 13 to generate an R−WF signal which is a mixed signal of the R channel and the WF channel (where the symbol “−” indicates that the phase has been inverted).

The L channel D/A converting unit 2 D/A converts the mixed signal of the L channel and WF channel generated by the mixing unit 10 (L+WF signal generated by the second adding unit 14) from a digital form to an analog form. The R channel D/A converting unit 3 D/A converts the mixed signal of the R channel and WF channel generated by the mixing unit 10 (R−WF signal generated by the third adding unit 15) from a digital from to an analog form.

L channel power amplifier 4 amplifies the L+WF signal D/A converted by the L channel D/A converting unit 2. More specifically, the L channel power amplifier 4 amplifies the L+WF signal generated by the second adding unit 14 in the mixing unit 10 and D/A converted by the L channel D/A converting unit 2, outputs the L+WF signal through the positive phase output terminal and outputs a −(L+WF) signal through the reverse phase output terminal.

The R channel power amplifier 5 amplifies the R−WF signal D/A converted by the R channel D/A converting unit 3. More specifically, the R channel power amplifier 5 amplifies the R−WF signal generated by the third adding unit 15 in the mixing unit 10 and D/A converted by the R channel D/A converting unit 3, outputs the R−WF signal through the positive phase output terminal and outputs the −(R−WF) signal through the reverse phase output terminal.

The L channel speaker 6 is connected to the output of the L channel power amplifier 4. More specifically, the L+WF signal output from the positive phase output terminal of the L channel power amplifier 4 is input to the + terminal of the L channel speaker 6. The −(L+WF) signal output from the reverse phase output terminal of the L channel power amplifier 4 is connected to the input of the − terminal of the L channel speaker 6. Thus, the voice signal (2L+2WF signal) having the 2L+2WF component is output from the L channel speaker 6. Here, the number “2” indicates that the voltage is double.

The R channel speaker 7 is connected to the output of the R channel power amplifier 5. More specifically, the R−WF signal output from the positive phase output terminal of the R channel power amplifier 5 is input to the + terminal of the R channel speaker 7. The −(R−WF) signal output from the reverse phase output terminal of the R channel power amplifier 5 is connected to the input of the − terminal of the R channel speaker 7. Thus, the voice signal (2R−2WF signal) having the 2R−2WF component is output from the R channel speaker 7.

The WF channel speaker 8 is BTL-connected to the output of the L channel power amplifier 4 and the output of the R channel power amplifier 5. More specifically, the L+WF signal output from the positive phase output terminal of the L channel power amplifier 4 is input to the + terminal of the WF channel speaker 8. The R−WF signal output from the positive phase output terminal of the R channel power amplifier 5 is connected to the input of the − terminal of the WF channel speaker 8. Thus, the voice signal (L−R+2WF signal) having the L−R+2WF component is output from the WF channel speaker 8.

From the L channel speaker 6, a voice signal of the 2WF component in addition to the 2L component is output. From the R channel speaker 7, a voice signal of the −2WF component in addition to the 2R component is output. However, at a listening position near the center between the L channel speaker 6 and R channel speaker 7, the voice signal of the 2WF component and the voice signal of the −2WF component are cancelled in the reverse phase. Thus, a user at the listening position may hear the voice signal as if the voice signal of the 2L component is only output from the L channel speaker 6 and the voice signal of the 2R component is only output from the R channel speaker 7.

From the WF channel speaker 8, a voice signal of the L component and a voice signal of the −R component are output in addition to the 2WF component. However, the voice signal (such as a vocal sound and a base sound) in a low frequency region output to the WF channel speaker 8 is normally a voice signal in the same phase in which the L component and the R component have a substantially equal intensity. For that, the voice signal of the L component and the voice signal of the −R component at a low frequency range are cancelled in the reverse phase for the WF channel speaker 8.

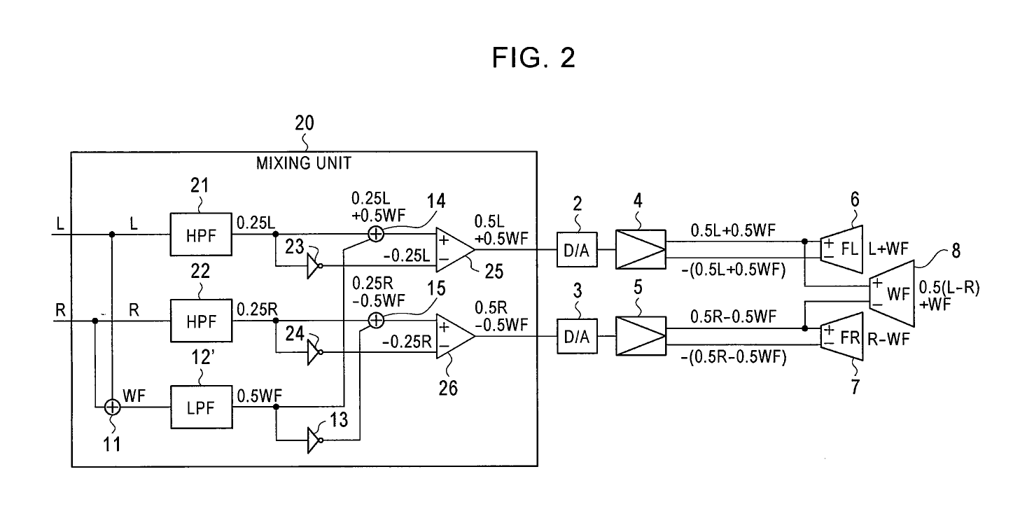

FIG. 2 illustrates another configuration example of the sound output apparatus according to this embodiment. In FIG. 2, the same numbers refer to the components having the same functions as in FIG. 1.

The sound output apparatus illustrated in FIG. 2 includes a mixing unit 20, an L channel D/A converting unit 2, an R channel D/A converting unit 3, an L channel power amplifier 4, an R channel power amplifier 5, an L channel speaker 6, an R channel speaker 7 and a WF channel speaker 8.

The mixing unit 20 may be implemented by a DSP, for example, and functionally includes a first adding unit 11, a WF channel LPF 12′, phase inverting units 13, 23, and 24, a second adding unit 14, a third adding unit 15, an L channel HPF 21, an R channel HPF 22 and amplifiers 25 and 26.

The WF channel LPF 12′ only allows a low frequency component of a WF signal generated by the first adding unit 11 to pass through. The WF channel LPF 12′ has an attenuation function and outputs the WF signal having a low frequency component only with voltage reduced half (where the number “0.5” indicates that the voltage is 0.5 times).

The L channel HPF 21 only allows a high frequency component of an L signal input to the second adding unit 14 to pass through. The L channel HPF 21 has an attenuation function and outputs an L signal having a high frequency component only with voltage reduced to ¼ (where the number “0.25” indicates that the voltage is 0.25 times). The phase inverting unit 23 inverts the phase of the 0.25L signal passed through the L channel HPF 21.

The R channel HPF 22 only allows a high frequency component of the R signal input to the third adding unit 15 to pass through. The R channel HPF 22 has an attenuation function and outputs an R signal having a high frequency component only with voltage reduced to ¼ (The number “0.25” indicates that the voltage is 0.25 times). The phase inverting unit 24 inverts the phase of the 0.25R signal passed through the R channel HPF 22.

The second adding unit 14 adds the 0.25L signal passed through the L channel HPF 21 and the 0.5WF signal passed through the WF channel LPF 12′ to generate a 0.25L+0.5WF signal. The third adding unit 15 adds the 0.25R signal passed through the R channel HPF 22 and the −0.5WF signal passed through the phase inverting unit 13 to generate a 0.25R−0.5WF signal.

The 0.25L+0.5WF signal output from the second adding unit 14 is input to the + terminal of the amplifier 25. The −0.25L signal output from the phase inverting unit 23 is input to the − terminal of the amplifier 25. The amplification efficiency of the amplifier 25 may be set at “1”, for example. Thus, the 0.5L+0.5WF signal is output from the amplifier 25.

The 0.25R−0.5WF signal output from the third adding unit 15 is input to the + terminal of the amplifier 26. The −0.25R signal output from the phase inverting unit 24 is input to the − terminal of the amplifier 26. The amplification efficiency of the amplifier 26 may be set at “1”, for example. Thus, the 0.5R−0.5WF signal is output from the amplifier 26.

The L channel D/A converting unit 2 D/A converts the 0.5L+0.5WF signal output from the amplifier 25 from a digital from to an analog form. The R channel D/A converting unit 3 D/A converts the 0.5R−0.5WF signal output from the amplifier 26 from a digital from to an analog form.

The L channel power amplifier 4 amplifies the 0.5L+0.5WF signal D/A converted by the L channel D/A converting unit 2, outputs the 0.5L+0.5WF signal through the positive phase output terminal and outputs the −(0.5L+0.5WF) signal through the reverse phase output terminal.

The R channel power amplifier 5 amplifies the 0.5R−0.5WF signal D/A converted by the R channel D/A converting unit 3, outputs the 0.5R−0.5WF signal through the positive phase output terminal and outputs the −(0.5R−0.5WF) signal through the reverse phase output terminal.

The 0.5L+0.5WF signal output from the positive phase output terminal of the L channel power amplifier 4 is input to the + terminal of the L channel speaker 6. The −(0.5L+0.5WF) signal output from the reverse phase output terminal of the L channel power amplifier 4 is input to the − terminal of the L channel speaker 6. Thus, the L+WF signal is output from the L channel speaker 6.

The 0.5R−0.5WF signal output from the positive phase output terminal of the R channel power amplifier 5 is input to the + terminal of the R channel speaker 7. The −(0.5R−0.5WF) signal output from the reverse phase output terminal of the R channel power amplifier 5 is input to the − terminal of the R channel speaker 7. Thus, the R−WF signal is output from the R channel speaker 7.

Through the BTL connection, the 0.5L+0.5WF signal output from the positive phase output terminal of the L channel power amplifier 4 is input to the + terminal of the WF channel speaker 8. The 0.5R−0.5WF signal output from the positive phase output terminal of the R channel power amplifier 5 is input to the − terminal of the WF channel speaker 8. Thus, the 0.5L−0.5R+WF signal is output from the WF channel speaker 8.

Here, the voice signal of the WF component output from the L channel speaker 6 and the voice signal of the −WF component output from the R channel speaker 7 are cancelled in the reverse phase at a listening position near the center between the L channel speaker 6 and the R channel speaker 7. The voice signal of the 0.5L component output from the WF channel speaker 8 and the voice signal of the −0.5R component in a low frequency region are cancelled in the reverse phase in the WF channel speaker 8.

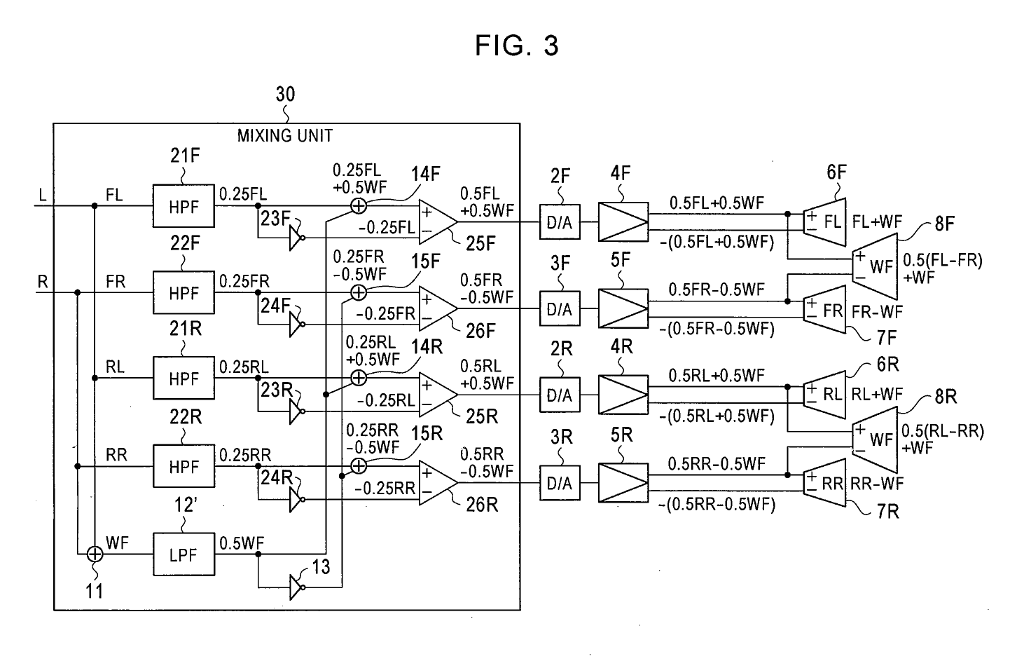

FIG. 3 illustrates another configuration example of the sound output apparatus according to this embodiment. In the example illustrated in FIG. 3, a speaker is provided in a front seat and a rear seat of a vehicle. In FIG. 3, the same numbers refer to the components having the same functions as the components illustrated in FIG. 2. The symbol “F” indicates one for a front seat, and the symbol “R” indicates one for a rear seat.

The sound output apparatus illustrated in FIG. 3 includes a mixing unit 30, L channel D/A converting units 2F and 2R, R channel D/A converting units 3F and 3R, L channel power amplifiers 4F and 4R, R channel power amplifiers 5F and 5R, L channel speakers 6F and 6R, R channel speakers 7F and 7R and WF channel speakers 8F and 8R.

The mixing unit 30 may be implemented by a DSP, for example, and functionally includes a first adding unit 11, a WF channel LPF 12′, phase inverting units 13, 23F, 23R, 24F, and 24R, a second adding unit 14F, a third adding unit 15F, a fourth adding unit 14R, a fifth adding unit 15R, a front seat L channel HPF 21F, a front seat R channel HPF 22F, a rear seat L channel HPF 21R, a rear seat R channel HPF 22R and amplifiers 25F, 25R, 26F, and 26R.

The mixing unit 30 generates (or distributes) a voice signal for a front seat (hereinafter, called an FL signal) and a voice signal for a rear seat (hereinafter, called an FR signal) from an L channel voice signal (L signal) input thereto. The mixing unit 20 generates (or distributes) a voice signal for a front seat (hereinafter, called an RL signal) and a voice signal for a rear seat (hereinafter, called an RR signal) from a voice signal (R signal) of an R channel input thereto.

The front seat L channel HPF 21F only allows a high frequency component of the FL signal input to the second adding unit 14F to pass through. The front seat L channel HPF 21F has an attenuation function and outputs the FL signal only having the high frequency component with voltage reduced to ¼.

The front seat R channel HPF 22F only allows a high frequency component of the FR signal input to the third adding unit 15F to pass through. The front seat R channel HPF 22F has an attenuation function and outputs the FR signal only having the high frequency component with voltage reduced to ¼.

The rear seat L channel HPF 21R only allows a high frequency component of the RL signal input to the fourth adding unit 14R to pass through. The rear seat L channel HPF 21 R has an attenuation function and outputs the RL signal only having the high frequency component with voltage reduced to ¼.

The rear seat R channel HPF 22R only allows a high frequency component of the RR signal input to the fifth adding unit 15R to pass through. The rear seat R channel HPF 22R has an attenuation function and outputs the RR signal only having the high frequency component with voltage reduced to ¼.

The phase inverting unit 23F inverts the phase of the 0.25FL signal passed through the front seat L channel HPF 21F. The phase inverting unit 24F inverts the phase of the 0.25FR signal passed through the front seat R channel HPF 22F. The phase inverting unit 23R inverts the phase of the 0.25RL signal passed through the rear seat L channel HPF 21 R. The phase inverting unit 24R inverts the phase of the 0.25RR signal passed through the rear seat R channel HPF 22R.

The second adding unit 14F adds the 0.25FL signal passed through the front seat L channel HPF 21F and the 0.5WF signal passed through the WF channel LPF 12′ to generate a 0.25FL+0.5WF signal. The third adding unit 15F adds the 0.25FR signal passed through the front seat R channel HPF 22F and the −0.5WF signal passed through the phase inverting unit 13 to generate a 0.25FR−0.5WF signal.

The fourth adding unit 14R adds the 0.25RL signal passed through the rear seat L channel HPF 21R and the 0.5WF signal passed through the WF channel LPF 12′ to generate a 0.25RL+0.5WF signal. The fifth adding unit 15R adds the 0.25RR signal passed through the rear seat R channel HPF 22R and the −0.5WF signal passed through the phase inverting unit 13 to generate a 0.25RR−0.5WF signal.

The 0.25FL+0.5WF signal output from the second adding unit 14F is input to the + terminal of the amplifier 25F. The −0.25FL signal output from the phase inverting unit 23F is input to the − terminal of the amplifier 25F. The amplification efficiency of the amplifier 25F may be set at “1”, for example. Thus, the 0.5FL+0.5WF signal is output from the amplifier 25F.

The 0.25FR−0.5WF signal output from the third adding unit 15F is input to the + terminal of the amplifier 26F. The −0.25FR signal output from the phase inverting unit 24F is input to the − terminal of the amplifier 26F. The amplification efficiency of the amplifier 26F may be set at “1”, for example. Thus, the 0.5FR−0.5WF signal is output from the amplifier 26F.

The 0.25RL+0.5WF signal output from the fourth adding unit 14R is input to the + terminal of the amplifier 25R. The −0.25RL signal output from the phase inverting unit 23R is input to the − terminal of the amplifier 25R. The amplification efficiency of the amplifier 25R may be set at “1”, for example. Thus, the 0.5RL+0.5WF signal is output from the amplifier 25R.

The 0.25RR−0.5WF signal output from the fifth adding unit 15R is input to the + terminal of the amplifier 26R. The −0.25RR signal output from the phase inverting unit 24R is input to the − terminal of the amplifier 26R. The amplification efficiency of the amplifier 26R may be set at “1”, for example. Thus, the 0.5RR−0.5WF signal is output from the amplifier 26R.

The front seat L channel D/A converting unit 2F D/A converts the 0.5FL+0.5WF signal output from the amplifier 25F from a digital form to an analog form. The front seat R channel D/A converting unit 3F D/A converts the 0.5FR−0.5WF signal output from the amplifier 26F from a digital form to an analog form.

The rear seat L channel D/A converting unit 2R D/A converts the 0.5RL+0.5WF signal output from the amplifier 25R from a digital form to an analog form. The rear seat R channel D/A converting unit 3R D/A converts the 0.5RR−0.5WF signal output from the amplifier 26R from a digital form to an analog form.

The front seat L channel power amplifier 4F amplifies the 0.5FL+0.5WF signal D/A converted by the front seat L channel D/A converting unit 2F, outputs the 0.5FL+0.5WF signal through the positive phase output terminal and outputs the −(0.5FL+0.5WF) signal through the reverse phase output terminal.

The front seat R channel power amplifier 5F amplifies the 0.5FR−0.5WF signal D/A converted by the front seat R channel D/A converting unit 3F, outputs the 0.5FR−0.5WF signal through the positive phase output terminal and outputs the −(0.5FR−0.5WF) signal through the reverse phase output terminal.

The rear seat L channel power amplifier 4R amplifies the 0.5RL+0.5WF signal D/A converted by the rear seat L channel D/A converting unit 2R, outputs the 0.5RL+0.5WF signal through the positive phase output terminal, and outputs the −(0.5RL+0.5WF) signal through the reverse phase output terminal.

The rear seat R channel power amplifier 5R amplifies the 0.5RR−0.5WF signal D/A converted by the rear seat R channel D/A converting unit 3R, outputs the 0.5RR31 0.5WF signal through the positive phase output terminal, and outputs the −(0.5RR−0.5WF) signal through the reverse phase output terminal.

The 0.5FL+0.5WF signal output from the positive phase output terminal of the front seat L channel power amplifier 4F is input to the + terminal of the front seat L channel speaker 6F. The −(0.5FL+0.5WF) signal output from the reverse phase output terminal of the front seat L channel power amplifier 4F is input to the − terminal of the front seat L channel speaker 6F. Thus, the FL+WF signal is output from the front seat L channel speaker 6F.

The 0.5FR−0.5WF signal output from the positive phase output terminal of the front seat R channel power amplifier 5F is input to the + terminal of the front seat R channel speaker 7F. The −(0.5FR−0.5WF) signal output from the reverse phase output terminal of the front seat R channel power amplifier 5F is input to the − terminal of the front seat R channel speaker 7F. Thus, the FR−WF signal is output from the front seat R channel speaker 7F.

The 0.5FL+0.5WF signal output from the positive phase output terminal of the front seat L channel power amplifier 4F is input to the + terminal of the front seat WF channel speaker 8F. The 0.5FR−0.5WF signal output from the positive phase output terminal of the front seat R channel power amplifier 5F is input to the − terminal of the front seat WF channel speaker 8F. Thus, the 0.5FL−0.5FR+WF signal is output from the front seat WF channel speaker 8F.

Here, the voice signal of the WF component output from the front seat L channel speaker 6F and the voice signal of the −WF component output from the front seat R channel speaker 7F are cancelled in the reverse phase at a listening position near the center between the front seat L channel speaker 6F and the front seat R channel speaker 7F. The voice signal of the 0.5FL component output from the front seat WF channel speaker 8F and the voice signal of the −0.5FR component in a low frequency region are cancelled in the reverse phase in the front seat WF channel speaker 8F.

The 0.5RL+0.5WF signal output from the positive phase output terminal of the rear seat L channel power amplifier 4R is input to the + terminal of the rear seat L channel speaker 6R. The −(0.5RL+0.5WF) signal output from the reverse phase output terminal of the rear seat L channel power amplifier 4R is input to the − terminal of the rear seat L channel speaker 6R. Thus, the RL+WF signal is output from the rear seat L channel speaker 6R.

The 0.5RR−0.5WF signal output from the positive phase output terminal of the rear seat R channel power amplifier 5R is input to the + terminal of the rear seat R channel speaker 7R. The −(0.5RR−0.5WF) signal output from the reverse phase output terminal of the rear seat R channel power amplifier 5R is input to the − terminal of the rear seat R channel speaker 7R. Thus, the RR−WF signal is output from the rear seat R channel speaker 7R.

The 0.5RL+0.5WF signal output from the positive phase output terminal of the rear seat L channel power amplifier 4R is input to the + terminal of the rear seat WF channel speaker 8R. The 0.5RR−0.5WF signal output from the positive phase output terminal of the rear seat R channel power amplifier 5R is input to the − terminal of the rear seat WF channel speaker 8R. Thus, the 0.5RL−0.5RR+WF signal is output from the rear seat WF channel speaker 8R.

Here, the voice signal of the WF component output from the rear seat L channel speaker 6R and the voice signal of the −WF component output from the rear seat R channel speaker 7R are cancelled in the reverse phase at a listening position near the center between the rear seat L channel speaker 6R and the rear seat R channel speaker 7R. The voice signal of the −0.5RR component and the voice signal of the 0.5RL component output from the rear seat WF channel speaker 8R in a low frequency region are cancelled in the reverse phase in the rear seat WF channel speaker 8R.

In a sound output apparatus according to this embodiment having the configuration as described above, the mixing units 10, 20, and 30 provided in a previous stage of the power amplifiers 2 and 3 (2F, 3F, 2R, 3R) may generate a voice signal of the WF channel. This may eliminate the necessity for a passive low pass filter in a subsequent stage of the power amplifiers 2 and 3 (2F, 3F, 2R, 3R).

The mixing unit 10, 20, or 30 is provided instead of a passive low pass filter. However, the mixing unit 10, 20, or 30 may be implemented by a DSP at lower cost than a passive low pass filter in the past implemented by a passive element for processing an analog voice signal amplified by the power amplifier 2 or 3 (2F, 3F, 2R, 3R).

In the sound output apparatus according to this embodiment, the voice signals of the WF channel generated by the first adding unit 11 in the mixing units 10, 20, and 30 are mixed with the L channel voice signal and R channel voice signal. After the mixed signal is amplified by the power amplifiers 2 and 3 (2F, 3F, 2R, 3R), a woofer voice signal is generated through the BTL connection between the outputs of the power amplifiers 2 and 3 (2F, 3F, 2R, 3R) and the WF channel speaker 8 (8F, 8R).

This may eliminate the necessity for a WF channel special power amplifier even though the mixing units 10, 20, and 30 in a previous stage of the power amplifiers 2 and 3 (2F, 3F, 2R, 3R) generate a voice signal of the WF channel. In other words, in the examples in FIG. 1 and FIG. 2, two power amplifiers 2 and 3 may be enough for driving a voice signal of the WF channel in addition to a voice signal of the L channel and R channel.

In the example in FIG. 3, only the four power amplifiers 2F, 3F, 2R, and 3R may drive voice signals of the front seat and rear seat WF channels in addition to the voice signals of the front seat and rear seat L channel and R channel. Moreover, in the example in FIG. 3, a what is called FADER function (which is a function of adjusting an amplification efficiency with an amplifier provided in a previous stage of the HPFs 21F, 22F, 21R, 22R) may output a front seat or rear seat voice signal only. Even in this case, a voice signal of the WF channel may be output in a stable manner from the WF channel speaker 8F or 8R.

With the aforementioned configurations, the sound output apparatus according to this embodiment is a sound output apparatus using BTL connection which may be manufactured at a reduced cost by eliminating the necessity for a passive LPF for generating a woofer voice signal.

According to the aforementioned embodiment, the amplifiers 25 and 26 and the phase inverting units 23 and 24 are provided in the example in FIG. 2 in order to adjust the voltage (amplitude) of a voice signal. However, the adjustment of the amplitude is not a gist of the present invention, and they are not required. In other words, as illustrated in FIG. 1, the sound output apparatus may be implemented without the amplifiers 25 and 26 and phase inverting units 23 and 24. Similarly, also in the example in FIG. 3 in which speakers are provided for a front seat and a rear seat, the sound output apparatus may be implemented without the amplifiers 25F, 25R, 26F, and 26R and phase inverting units 23F, 23R, 24F, and 24R. In other words, though the appended claims do not described a coefficient that expresses the amplitude, it does not mean that the amplitude is limited to once but it means that the amplitude is not limited particularly.

According to the embodiment, the HPFs 21 and 22 are provided in the example in FIG. 2 for only allowing a high frequency component of an L channel voice signal and an R channel voice signals to pass through. However, they are not required. In other words, the sound output apparatus may be implemented as in FIG. 1, without the HPFs 21 and 22. However, providing the HPFs 21 and 22 preferably prevents the output of a low frequency component from the L channel speaker 6 and R channel speaker 7 and eliminates the overlap with the low frequency component output from the WF channel speaker 8. Similarly, also in the example in FIG. 3, the HPFs 21F, 21R, 22F, and 22R may be omitted.

Having described according to the embodiment that the mixing units 10, 20, and 30 are implemented by DSPs, for example, the present invention is not limited thereto. For example, an analog circuit employing an operational amplifier may be used to implement the mixing unit 10, 20, or 30. However, implementing the mixing units 10, 20, and 30 with DSPs are preferable for its lower manufacturing cost.

According to the embodiment, an L channel voice signal and a WF channel voice signal are added to generate an L+WF signal while an R channel voice signal and a voice signal of the WF channel having the inverted phase are added to generate an R−WF signal. However, the present invention is not limited thereto.

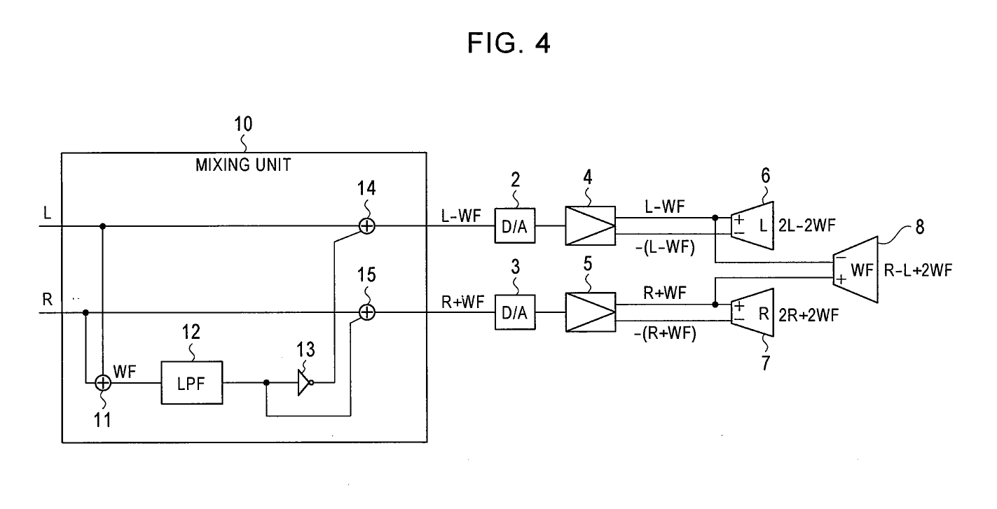

For example, as in FIG. 4 illustrating a variation of the configuration in FIG. 1, an L channel voice signal and a WF channel voice signal having the inverted phase may be added in the second adding unit 14 to generate an L−WF signal. On the other hand, a voice signal of the R channel and a voice signal of the WF channel may be added in the third adding unit 15 to generate an R+WF signal.

In this case, the L channel power amplifier 4 amplifies the L−WF signal generated by the second adding unit 14, outputs the L−WF signal through the positive phase output terminal and outputs the −(L−WF) signal through the reverse phase output terminal. The R channel power amplifier 5 amplifies the R+WF signal generated by the third adding unit 15, outputs the R+WF signal through the positive phase output terminal and outputs the −(R+WF) signal through the reverse phase output terminal.

The L−WF signal and −(L−WF) signal output from the positive phase output terminal and reverse phase output terminal of the L channel power amplifier 4 are input to the + terminal and − terminal of the L channel speaker 6. The R+WF signal and −(R+WF) signal output from the positive phase output terminal and reverse phase output terminal of the R channel power amplifier 5 are input to the + terminal and − terminal of the R channel speaker 7.

The L−WF signal output from the positive phase output terminal of the L channel power amplifier 4 is input to the − terminal of the WF channel speaker 8. The R+WF signal output from the positive phase output terminal of the R channel power amplifier 5 is input to the + terminal of the WF channel speaker 8.

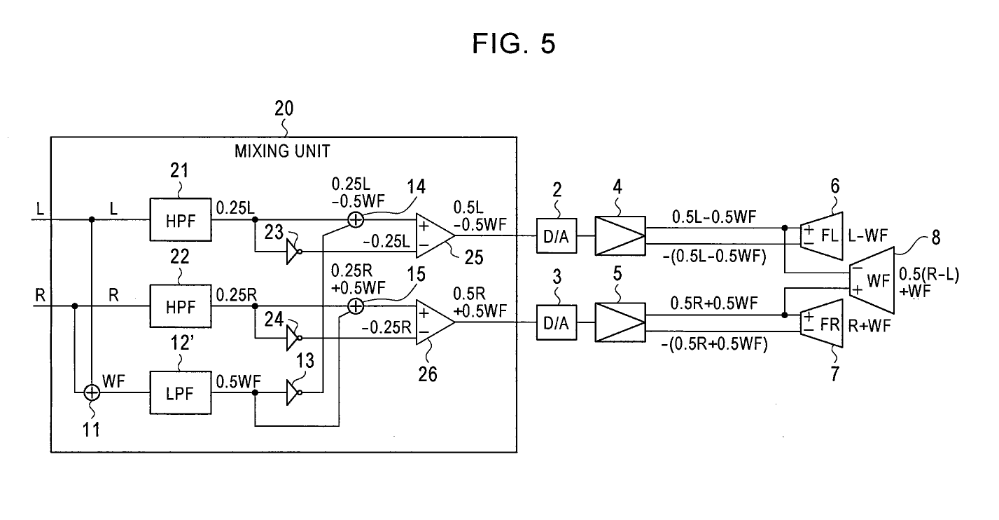

As in FIG. 5 illustrating a variation of the configuration in FIG. 2, an L channel voice signal and a WF channel voice signal having the inverted phase may be added in the second adding unit 14 to generate a 0.25L−0.5WF signal. On the other hand, an R channel voice signal and a WF channel voice signal may be added in the third adding unit 15 to generate a 0.25R+0.5WF signal.

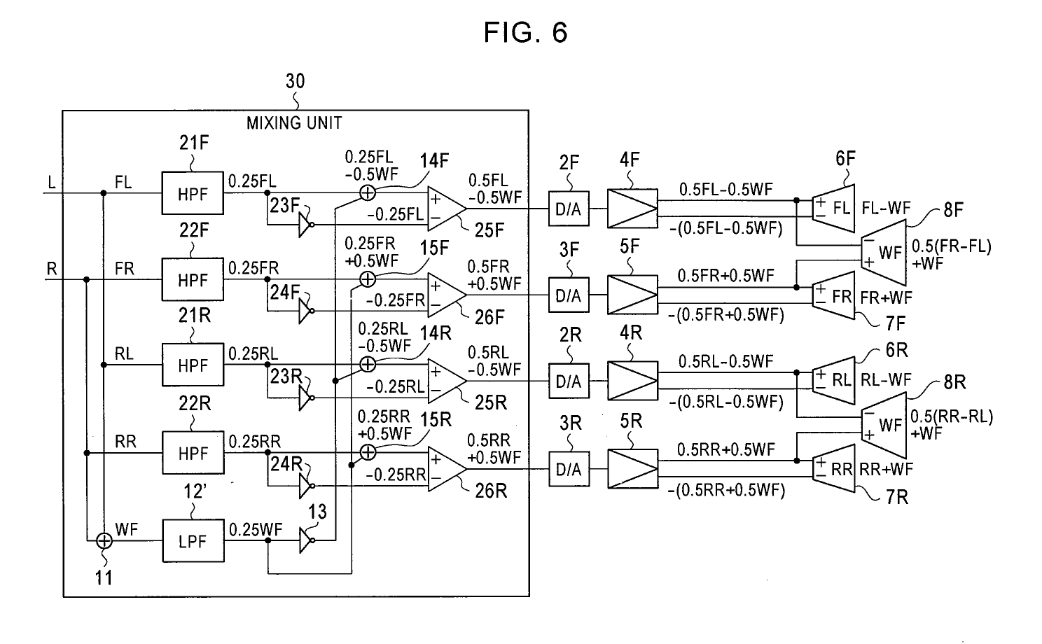

Alternatively, as in FIG. 6 illustrating a variation of the configuration in FIG. 3, a front seat L channel voice signal and WF channel voice signal having the inverted phase may be added in the second adding unit 14F to generate a 0.25FL−0.5WF signal. On the other hand, a front seat R channel voice signal and a WF channel voice signal may be added in the third adding unit 15F to generate a 0.25FR+0.5WF signal.

Similarly, a rear seat L channel voice signal and WF channel voice signal having the inverted phase may be added in the fourth adding unit 14R to generate a 0.25RL−0.5WF signal. On the other hand, a rear seat R channel voice signal and a WF channel voice signal may be added in the fifth adding unit 15R to generate a 0.25RR+0.5WF signal.

In this case, the front seat L channel power amplifier 4F amplifies the 0.5FL−0.5WF signal generated by the amplifier 25F. The front seat R channel power amplifier 5F amplifies the 0.5FR+0.5WF signal generated by the amplifier 26F. The rear seat L channel power amplifier 4R amplifies the 0.5RL−0.5WF signal generated by the amplifier 25R. The rear seat R channel power amplifier 5R amplifies the 0.5RR+0.5WF signal generated by the amplifier 26R.

The 0.5FL−0.5WF signal output from the positive phase output terminal of the front seat L channel power amplifier 4F is input to the − terminal of the front seat WF channel speaker 8F. The 0.5FR+0.5WF signal output from the positive phase output terminal of the front seat R channel power amplifier 5F is input to the + terminal of the front seat WF channel speaker 8F.

The 0.5RL−0.5WF signal output from the positive phase output terminal of the rear seat L channel power amplifier 4R is input to the − terminal of the rear seat WF channel speaker 8R. The 0.5RR+0.5WF signal output from the positive phase output terminal of the rear seat R channel power amplifier 5R is input to the + terminal of the rear seat WF channel speaker 8R.

Having described according to the embodiment that the positive phase output terminals of two power amplifiers are BTL connected to a WF channel speaker, the present invention is not limited thereto. For example, the reverse phase output terminals of two power amplifiers may be BTL connected to a WF channel speaker. In this case, the part connected to the + terminal of the WF channel speaker according to the embodiment is changed to connect to the − terminal, and the part connected to the − terminal is changed to connect to the + terminal.

Although preferred embodiments have been described in detail, the present invention is not limited to these specific embodiments. Rather, various modifications and changes can be made without departing from the scope of the present invention as described in the accompanying claims. Accordingly, all such modifications are intended to be included within the scope of this invention as defined in the following claims.

What is claimed is:

1. A sound output apparatus configured to provide a monaural output through a bridge connection of two outputs of a stereo amplifier, the apparatus comprising:
a mixing unit configured to receive and mix an L (left) channel voice signal and an R (right) channel voice signal to generate a mixed signal of the L channel and a WF (woofer) channel, and generate a mixed signal of the R channel and the WF channel;
an L channel power amplifier configured to amplify a mixed signal of the L channel and the WF channel generated by the mixing unit;
an R channel power amplifier configured to amplify a mixed signal of the R channel and the WF channel generated by the mixing unit;
an L channel speaker connected to an output of the L channel power amplifier;
an R channel speaker connected to an output of the R channel power amplifier; and
a WF channel speaker bridge-connected to an output of the L channel power amplifier and to an output of the R channel power amplifier.

2. The sound output apparatus according to claim 1, further including in the mixing unit:
a first adding unit configured to add the L channel voice signal and the R channel voice signal to generate a WF channel voice signal;
a WF channel low pass filter configured to pass only low frequency components of the WF channel voice signal generated by the first adding unit to pass through;
a phase inverting unit configured to invert a phase of the WF channel voice signal passed through the WF channel low pass filter;
a second adding unit configured to add the L channel voice signal and the WF channel voice signal passed through the WF channel low pass filter, to generate an L+WF signal representing a mixed signal of the L channel and the WF channel; and
a third adding unit configured to add the R channel voice signal and the WF channel voice signal having the phase inverted by the phase inverting unit, to generate an R−WF signal representing a mixed signal of the R channel and the WF channel;
wherein the L channel power amplifier amplifies the L+WF signal generated by the second adding unit;
wherein the R channel power amplifier amplifies the R−WF signal generated by the third adding unit; and
wherein the L+WF signal amplified by the L channel power amplifier is input to a + terminal of the WF channel speaker, and the R−WF signal amplified by the R channel power amplifier is input to a − terminal of the WF channel speaker.

3. The sound output apparatus according to claim 2, wherein:
the L channel power amplifier amplifies the L+WF signal generated by the second adding unit, outputs an L+WF signal through a positive phase output terminal, and outputs a −(L+WF) signal through a reverse phase output terminal;
the R channel power amplifier amplifies the R−WF signal generated by the third adding unit, outputs an R−WF signal through a positive phase output terminal, and outputs a −(R−WF) signal through a reverse phase output terminal;
the L+WF signal and the −(L+WF) signal output from the positive phase output terminal and the reverse phase output terminal of the L channel power amplifier, are input to the + terminal and − terminal of the L channel speaker, respectively;
the R−WF signal and the −(R−WF) signal output from the positive phase output terminal and the reverse phase output terminal of the R channel power amplifier, are input to the + terminal and − terminal of the R channel speaker, respectively.

4. The sound output apparatus according to claim 2, further comprising:
an L channel high pass filter configured to pass only high frequency components of the L channel voice signal input to the second adding unit; and
an R channel high pass filter configured to pass only high frequency components of the R channel voice signal input to the third adding unit
wherein the second adding unit is configured to add the L channel voice signal passed through the L channel high pass filter and the WF channel voice signal passed through the WF channel low pass filter, to generate an L+WF signal; and
wherein the third adding unit is configured to add the R channel voice signal passed through the R channel high pass filter and the WF channel voice signal having the phase inverted by the phase inverting unit, to generate an R−WF signal.

5. The sound output apparatus according to claim 1, further including in the mixing unit:
a first adding unit configured to add the L channel voice signal and the R channel voice signal to generate a WF channel voice signal;
a WF channel low pass filter configured to pass only low frequency components of the WF channel voice signal generated by the first adding unit;
a phase inverting unit configured to invert the phase of the WF channel voice signal passed through the WF channel low pass filter;
a second adding unit configured to add the L channel voice signal and the WF channel voice signal having the phase inverted by the phase inverting unit, to generate an L−WF signal representing a mixed signal of the L channel and the WF channel; and
a third adding unit configured to add the R channel voice signal and the WF channel voice signal passed through the WF channel low pass filter, to generate an R+WF signal representing a mixed signal of the R channel and the WF channel;
wherein
the L channel power amplifier amplifies the L−WF signal generated by the second adding unit;
the R channel power amplifier amplifies the R+WF signal generated by the third adding unit; and
the L−WF signal amplified by the L channel power amplifier is input to a − terminal of the WF channel speaker, and the R+WF signal amplified by the R channel power amplifier is input to a + terminal of the WF channel speaker.

6. The sound output apparatus according to claim 5, wherein:
the L channel power amplifier amplifies the L−WF signal generated by the second adding unit, outputs an L−WF signal through a positive phase output terminal, and outputs a −(L−WF) signal through a reverse phase output terminal;
the R channel power amplifier amplifies the R+WF signal generated by the third adding unit, outputs an R+WF signal through a positive phase output terminal, and outputs a −(R+WF) signal through a reverse phase output terminal;
the L−WF signal and the −(L−WF) signal output from the positive phase output terminal and the reverse phase output terminal of the L channel power amplifier, are input to the + terminal and − terminal of the L channel speaker, respectively;
the R+WF signal and the −(R+WF) signal output from the positive phase output terminal and reverse phase output terminal of the R channel power amplifier, are input to the + terminal and − terminal of the R channel speaker, respectively.

7. The sound output apparatus according to claim 5, further comprising:
an L channel high pass filter configured to pass only high frequency components of the L channel voice signal input to the second adding unit; and
an R channel high pass filter configured to pass only high frequency components of the R channel voice signal input to the third adding unit, wherein:
the second adding unit configured to add the L channel voice signal passed through the L channel high pass filter and the WF channel voice signal having the phase inverted by the phase inverting unit, to generate an L−WF signal; and
the third adding unit configured to add the R channel voice signal passed through the R channel high pass filter and the WF channel voice signal passed through the WF channel low pass filter, to generate an R+WF signal.

8. The sound output apparatus according to claim 1, wherein:
the L channel voice signal contains two voice signals for a front seat and rear seat of a vehicle, respectively, and the R channel voice signal contains two voice signals for the front seat and the rear seat, respectively;
the L channel power amplifier includes an L channel power amplifier for the front seat and an L channel power amplifier for the rear seat;
the R channel power amplifier includes an R channel power amplifier for the front seat and an R channel power amplifier for the rear seat;
the L channel speaker includes an L channel speaker for the front seat and an L channel speaker for the rear seat;
the R channel speaker includes an R channel speaker for the front seat and an R channel speaker for the rear seat;
the WF channel speaker includes a WF channel speaker for the front seat and a WF channel speaker for the rear seat;
the mixing unit generates two voice signals for the front seat and the rear seat from the L channel voice signal input thereto, and generates two voice signals for the front seat and the rear seat from the R channel voice signal input thereto;
the mixing unit further includes
a first adding unit which adds the L channel voice signal and R channel voice signal input thereto to generate a WF channel voice signal;
a WF channel low pass filter configured to pass only low frequency components of the WF channel voice signal generated by the first adding unit;
a phase inverting unit configured to invert the phase of the WF channel voice signal passed through the WF channel low pass filter;
a second adding unit configured to add an L channel voice signal for the front seat and the WF channel voice signal passed through the WF channel low pass filter, to generate an FL+WF signal representing a mixed signal of the front seat L channel and the WF channel;
a third adding unit configured to add the front seat R channel voice signal and the WF channel voice signal having the phase inverted by the phase inverting unit, to generate an FR−WF signal representing a mixed signal of the front seat R channel and the WF channel;
a fourth adding unit configured to add the rear seat L channel voice signal and the WF channel voice signal passed through the WF channel low pass filter, to generate an RL+WF signal, representing a mixed signal of the rear seat L channel and the WF channel; and
a fifth adding unit configured to add the rear seat R channel voice signal and the WF channel voice signal having the phase inverted by the phase inverting unit, to generate an RR−WF signal representing a mixed signal of the rear seat R channel and the WF channel;
the front seat L channel power amplifier amplifies the FL+WF signal generated by the second adding unit;
the front seat R channel power amplifier amplifies the FR−WF signal generated by the third adding unit;
the rear seat L channel power amplifier amplifies the RL+WF signal generated by the fourth adding unit;
the rear seat R channel power amplifier amplifies the RR−WF signal generated by the fifth adding unit;
the FL+WF signal amplified by the front seat L channel power amplifier is input to a + terminal of the front seat WF channel speaker, and the FR−WF signal amplified by the front seat R channel power amplifier is input to a − terminal of the front seat WF channel speaker; and
the RL+WF signal amplified by the rear seat L channel power amplifier is input to a + terminal of the rear seat WF channel speaker, and the RR−WF signal amplified by the rear seat R channel power amplifier is input to a − terminal of the rear seat WF channel speaker.

9. The sound output apparatus according to claim 8, further comprising:
a front seat L channel high pass filter configured to pass only high frequency components of the front seat L channel voice signal input to the second adding unit;
a front seat R channel high pass filter configured to pass only high frequency components of the front seat R channel voice signal input to the third adding unit;
a rear seat L channel high pass filter configured to pass only high frequency components of the rear seat L channel voice signal input to the fourth adding unit; and
a rear seat R channel high pass filter configured to pass only high frequency components of the rear seat R channel voice signal input to the fifth adding unit, wherein
the second adding unit adds the front seat L channel voice signal passed through the front seat L channel high pass filter and the WF channel voice signal passed through the WF channel low pass filter, to generate a FL+WF signal;
the third adding unit adds the front seat R channel voice signal passed through the front seat R channel high pass filter and the WF channel voice signal having the phase inverted by the phase inverting unit, to generate a FR−WF signal;
the fourth adding unit adds the rear seat L channel voice signal pass through the rear seat L channel high pass filter and the WF channel voice signal passed through the WF channel low pass filter, to generate an RL+WF signal; and
the fifth adding unit adds the rear seat R channel voice signal passed through the rear seat R channel high pass filter and the WF channel voice signal having the phase inverted by the phase inverting unit, to generate an RR−WF signal.

10. The sound output apparatus according to claim 1, wherein:
the L channel voice signal contains two voice signals for a front seat and rear seat of a vehicle, respectively, and the R channel voice signal contains two voice signals for the front seat and the rear seat, respectively;
the L channel power amplifier includes an L channel power amplifier for the front seat and an L channel power amplifier for the rear seat;
the R channel power amplifier includes an R channel power amplifier for the front seat and an R channel power amplifier for the rear seat;
the L channel speaker includes an L channel speaker for the front seat and an L channel speaker for the rear seat;
the R channel speaker includes an R channel speaker for the front seat and an R channel speaker for the rear seat;
the WF channel speaker includes a WF channel speaker for the front seat and a WF channel speaker for the rear seat;
the mixing unit generates two voice signals for the front seat and the rear seat from the L channel voice signal input thereto and generates two voice signals for the front seat and the rear seat from the R channel voice signal input thereto;
the mixing unit further includes
a first adding unit which adds the L channel voice signal and R channel voice signal input thereto to generate a WF channel voice signal;
a WF channel low pass filter which only allows a low frequency component of the WF channel voice signal generated by the first adding unit to pass through;
a phase inverting unit which inverts the phase of the WF channel voice signal passed through the WF channel low pass filter;
a second adding unit which adds an L channel voice signal for the front seat and the WF channel voice signal having the phase inverted by the phase inverting unit to generate an FL−WF signal which is a mixed signal of the front seat L channel and the WF channel;
a third adding unit which adds the front seat R channel voice signal and the WF channel voice signal passed through the WF channel low pass filter to generate an FR+WF signal which is a mixed signal of the front seat R channel and the WF channel;
a fourth adding unit which adds the rear seat L channel voice signal and the WF channel voice signal having the phase inverted by the phase inverting unit to generate an RL−WF signal which is a mixed signal of the rear seat L channel and the WF channel; and
a fifth adding unit which adds the rear seat R channel voice signal and the WF channel voice signal passed through the WF channel low pass filter to generate an RR+WF signal which is a mixed signal of the rear seat R channel and the WF channel;
the front seat L channel power amplifier amplifies the FL−WF signal generated by the second adding unit;
the front seat R channel power amplifier amplifies the FR+WF signal generated by the third adding unit;
the rear seat L channel power amplifier amplifies the RL−WF signal generated by the fourth adding unit;
the rear seat R channel power amplifier amplifies the RR+WF signal generated by the fifth adding unit;
the FL−WF signal amplified by the front seat L channel power amplifier is input to a − terminal of the front seat WF channel speaker, and the FR+WF signal amplified by the front seat R channel power amplifier is input to a + terminal of the front seat WF channel speaker; and
the RL−WF signal amplified by the rear seat L channel power amplifier is input to a − terminal of the rear seat WF channel speaker, and the RR+WF signal amplified by the rear seat R channel power amplifier is input to a + terminal of the rear seat WF channel speaker.

11. The sound output apparatus according to claim 10, further comprising:
a front seat L channel high pass filter configured to pass only high frequency components of the front seat L channel voice signal input to the second adding unit;
a front seat R channel high pass filter configured to pass only high frequency components of the front seat R channel voice signal input to the third adding unit;
a rear seat L channel high pass filter configured to pass only high frequency components of the rear seat L channel voice signal input to the fourth adding unit; and
a rear seat R channel high pass filter configured to pass only high frequency components of the rear seat R channel voice signal input to the fifth adding unit, wherein
the second adding unit adds the front seat L channel voice signal passed through the front seat L channel high pass filter and the WF channel voice signal having the phase inverted by the phase inverting unit, to generate a FL−WF signal;
the third adding unit adds the front seat R channel voice signal passed through the front seat R channel high pass filter and the WF channel voice signal passed through the WF channel low pass filter, to generate a FR+WF signal;
the fourth adding unit adds the rear seat L channel voice signal pass through the rear seat L channel high pass filter and the WF channel voice signal having the phase inverted by the phase inverting unit to generate an RL−WF signal; and
the fifth adding unit adds the rear seat R channel voice signal passed through the rear seat R channel high pass filter and the WF channel voice signal passed through the WF channel low pass filter to generate an RR+WF signal.
